(19) United States
(12) Patent Application Publication
(10) Pub. No.: US 2026/0044650 A1
(43) Pub. Date: Feb. 12, 2026

(54) CREEP AGE FORMING METHOD AND DEVICE BASED ON DIGITAL TWIN TECHNOLOGY

(71) Applicant: Central South University, Changsha (CN)

(72) Inventors: Lihua ZHAN, Changsha (CN); Shuangbo LI, Changsha (CN); Youliang YANG, Changsha (CN)

(73) Assignee: Central South University, Changsha (CN)

(21) Appl. No.: 19/294,689

(22) Filed: Aug. 8, 2025

(30) Foreign Application Priority Data
Aug. 8, 2024 (CN) 2024110815125

(51) Int. Cl. G06F 30/27; G06F 30/23; G06N 3/0442

(52) U.S. Cl. CPC G06F 30/27; G06F 30/23; G06N 3/0442

(57) ABSTRACT

A creep age forming method and device based on digital twin technology provided by the present disclosure. The method acquires sensor data of the aluminum alloy panel during a creep age forming process and inputs the sensor data into the first prediction model and obtains the predicted springback amount and yield strength output by the first prediction model. First difference values between the predicted springback amount and yield strength with the target springback amount and yield strength are determined. Based on the first difference values, first process parameters are determined for updating the process of the aluminum alloy panel by using the second prediction model. The first process parameters are sent to the autoclave, and the autoclave is controlled to perform a process operation with the first process parameters. The present disclosure can adjust the process based on real-time sensor data to obtain components with precise forming and target performance.

### CROSS-REFERENCE TO RELATED APPLICATION

The present disclosure claims the benefit and priority of Chinese Patent disclosure No. 202411081512.5 filed with the China National Intellectual Property Administration on Aug. 8, 2024, the disclosure of which is incorporated by reference herein in its entirety as part of the present disclosure.

### TECHNICAL FIELD

The present disclosure relates to the technical field of creep age forming, and particularly to a creep age forming method and device based on digital twin technology.

### BACKGROUND

Large thin-walled components are important components and key load-bearing structures of aerospace equipment, accounting for more than 40% of the weight of the aircraft/rocket structure. Creep age forming technology is often used for the forming of large thin-walled components, which has the advantage of enabling the components to achieve both forming and strength improvement simultaneously. Therefore, it is widely used in the manufacturing of large thin-walled components in aerospace.

For the creep age forming of large thin-walled components, it is necessary to place the component on a mold, and use the vacuum bag to shrink during a vacuum process at room temperature to make the panel and mold fit as closely as possible. Then, the mold and component are placed in an autoclave for heating and pressurization until the component is fitted to the mold, to initiate a creep age forming phase. However, after entering the autoclave, due to the high temperature and high-pressure environment, it is impossible to know in real time when the panel fits the mold in a real situation and whether the component deflects during the fitting process. It can only be known after the creep age forming process is completed and the autoclave is opened. A total process flow of creep forming under certain conditions can be more than ten hours. Therefore, if the actual fitting condition does not match the pre-simulation, a previously set process will not be able to achieve the forming precision.

### SUMMARY

To address technical problems that the existing creep age forming process cannot adjust a previously set process, resulting in a performance of a large thin-walled component failing to meet a target precision, embodiments of the present disclosure provide a creep age forming method and device based on digital twin technology.

Technical solutions of the embodiments of the present disclosure are implemented as follows:

An embodiment of the present disclosure provides a creep age forming method based on digital twin technology, the method includes: acquiring sensor data of an aluminum alloy panel during a creep age forming process; inputting the sensor data into a first prediction model and obtaining a predicted springback amount and a yield strength output by the first prediction model; wherein, the first prediction model is obtained by using a first training method on an initial network model, and the initial network model is an LSTM algorithm model; inputs of the first prediction model include time, temperature, heating rate and pressure; outputs of the first prediction model include the predicted springback amount and yield strength of the aluminum alloy panel; comparing the predicted springback amount and yield strength with a target springback amount and yield strength, and determining first difference values between the predicted springback amount and yield strength and the target springback amount and yield strength; determining, based on the first difference values, first process parameters for updating a process of the aluminum alloy panel by using a second prediction model; sending the first process parameters to an autoclave, and controlling the autoclave to perform process operations with the first process parameters; wherein, the second prediction model is obtained by using a second training method on the initial network model; inputs of the second prediction model include process updating time, time, temperature, heating rate and pressure; outputs of the second prediction model include the predicted springback amount and yield strength of the aluminum alloy panel.

In an embodiment, obtaining the first prediction model includes: conducting creep age forming tests on a specimen-level aluminum alloy and obtaining a sample data set; constructing a material constitutive equation using the sample data set; performing a finite element simulation on a creep age forming process of a component-level aluminum alloy panel, based on the material constitutive equation, and obtaining a corresponding relationship between strain amount and displacement of a feature point on the aluminum alloy panel at different times; determining, based on the corresponding relationship, initial process parameters of the aluminum alloy panel and the springback amount and yield strength at mold-fitting time during the finite element simulation process; taking the initial process parameters and the springback amount and yield strength at the mold-fitting time as first training samples and training the initial network model to obtain the first prediction model.

In an embodiment, the material constitutive equation includes:

$$ε1 = f ( σ , T , t , γ ) = f ( σ ) f ( T ) f ( γ ) f ( t ) , \qquad formula ( 1 )$$

wherein, ε1 is a creep strain; σ is an applied creep stress; T is a creep temperature; γ is a creep heating rate; t is a creep time, and f(σ), f(T), f(γ), f(t) are creep stress function, a creep temperature function, a creep heating rate function and a creep time function, respectively.

In an embodiment, obtaining the sample data set includes: conducting creep age forming tests on a specimen-level aluminum alloy and obtaining an initial sample data set; determining an optimal setting range for a K-value in a K-nearest neighbor algorithm; setting the K-value in the K-nearest neighbor algorithm based on the optimal setting range, and expanding the initial sample data set based on the K-nearest neighbor algorithm with the K-value setting to generate a new sample data set.

In an embodiment, the corresponding relationship between strain amount and displacement of feature point on the aluminum alloy panel at different times includes:

$$ε2 = \frac{L - L 0}{L 0} , \qquad formula ( 2 )$$

Wherein, ε2 is the strain of the feature point on the aluminum alloy panel at different times, L0 represents a distance between an initial position of the feature point and the mold, and L denotes a distance between a position of the feature point on the aluminum alloy panel and the mold at different times.

In an embodiment, training the initial network model to obtain the first prediction model includes: selecting one of SGD, Adam, Adamax, or RMSprop as an algorithm optimizer for the LSTM algorithm model, and one of Sigmiod, Tanh, or ReLU as an activation function for the LSTM algorithm model; training the initial network model with the selected algorithm optimizer and the selected activation function as model parameters to obtain the first prediction model.

In an embodiment, obtaining the second prediction model includes: during the finite element simulation process, defining a time when room temperature loading is completed as a starting time, and a time when the aluminum alloy panel is completely fitted to the mold as an ending time; determining a plurality of process update times between the starting time and the ending time according to a preset process update frequency to obtain a process update time sequence; acquiring finite element simulation process data corresponding to each process update time in the process update time sequence; training the initial network model using the process update time sequence and the finite element simulation process data corresponding to each process update time in the process update time sequence as second training data, and obtaining the second prediction model.

In an embodiment, determining the plurality of process update times includes: defining a time when the room temperature loading is completed as a starting time T1, a time when the aluminum alloy panel is completely fitted the mold after the aluminum alloy panel is put into the autoclave for high-temperature loading as an ending time t1, a duration from T1 to t1 as T, and a process update frequency as f.

Then, a process update time T2 is:

$$T 2 = T \times f + T 1 ;$$

A process update time T3 is:

$$T 3 = T \times f + T 2 ;$$

By analogy, a process update time Tn is:

$$Tn = T \times f + Tn - 1.$$

In an embodiment, after determining the first process parameters for updating the process of the aluminum alloy panel, the method further includes: after a preset time interval, acquiring sensor data of the aluminum alloy panel during the creep age forming process again; inputting the sensor data into the first prediction model and obtaining the predicted springback amount and yield strength output by the first prediction model; comparing the predicted springback amount and yield strength with the target springback amount and yield strength, and determining the first difference values between the predicted springback amount and yield strength and the target springback amount and yield strength; based on the first difference values, determining the first process parameters for updating the process of the aluminum alloy panel by using the second prediction model, sending the first process parameters to the autoclave, and controlling the autoclave to perform a process operation according to the first process parameters, and repeating the above operations until the predicted springback amount and yield strength are no difference from the target springback amount and yield strength.

An embodiment of the present disclosure also provides a creep age forming device based on digital twin technology, including: a sealed vacuum bag, an autoclave, a high-temperature strain gauge, a temperature sensor, a pressure sensor and a processor; the sealed vacuum bag is connected to the high-temperature strain gauge, the temperature sensor and the pressure sensor, and is used for shrinking during a vacuum pumping process to make the component fit the mold; the autoclave is connected to the high-temperature strain gauge, the temperature sensor and the pressure sensor, and is used for making the component fit the mold; the autoclave is connected with the high-temperature strain gauge, the temperature sensor and the pressure sensor, and is used for entering a creep age forming stage after the component is fitted to the mold under heating and pressure conditions; the high-temperature strain gauge is used for collecting state data of the component; the temperature sensor is configured to collect temperature data, and the pressure sensor is configured to collect pressure data; and the processor is configured to execute the steps of the method described above.

The creep age forming method and device based on digital twin technology provided by the embodiments of the present disclosure acquire sensor data of the aluminum alloy panel during a creep age forming process; input the sensor data into the first prediction model and obtain the predicted springback amount and yield strength output by the first prediction model; compare the predicted springback amount and yield strength with the target springback amount and yield strength; determine the first difference values between the predicted springback amount and yield strength and the target springback amount and yield strength; based on the first difference values, determine first process parameters for updating the process of the aluminum alloy panel by using the second prediction model; send the first process parameters to the autoclave, and control the autoclave to perform a process operation with the first process parameters. The solution provided by the present disclosure can adjust the process based on real-time sensor data to obtain components with precise forming and target performance.

### BRIEF DESCRIPTION OF DRAWINGS

FIG. 1 is a schematic flow chart of a creep age forming method based on digital twin technology according to an embodiment of the present disclosure;

FIG. 2 is a schematic structural diagram of a digital twinning system established according to an embodiment of the present disclosure;

FIG. 3 is a schematic structural diagram of a computer device according to an embodiment of the present disclosure.

### DETAILED DESCRIPTION OF THE EMBODIMENTS

The present disclosure will be further described in detail with reference to the drawings and embodiments.

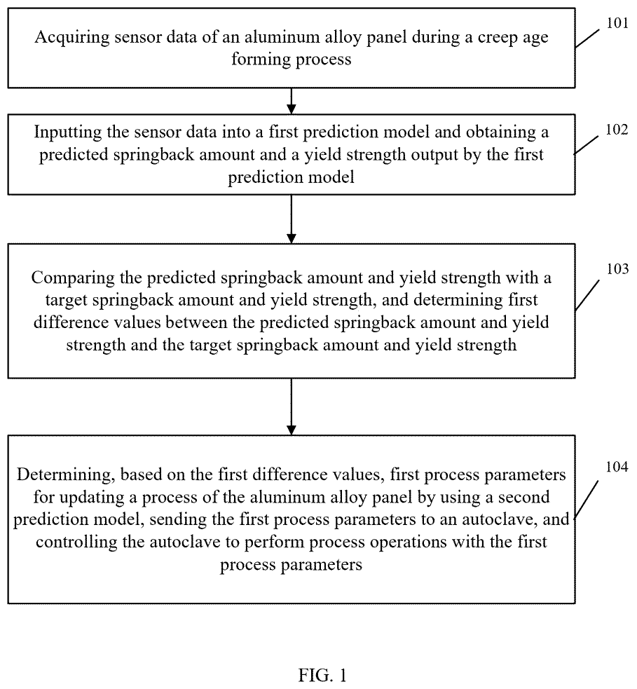

An embodiment of the present disclosure provides a creep age forming method based on digital twin technology, as shown in FIG. 1, the method includes:
Step 101: acquiring sensor data of an aluminum alloy panel during a creep age forming process;
Step 102: inputting the sensor data into a first prediction model and obtaining a predicted springback amount and a yield strength output by the first prediction model. The first prediction model is obtained by using a first training method on an initial network model, and the initial network model is an LSTM algorithm model; inputs of the first prediction model include time, temperature, heating rate and pressure; and outputs of the first prediction model include the predicted springback amount and yield strength of the aluminum alloy panel;
Step 103: comparing the predicted springback amount and yield strength with a target springback amount and yield strength, and determining first difference values between the predicted springback amount and yield strength and the target springback amount and yield strength;
Step 104: determining, based on the first difference values, first process parameters for updating a process of the aluminum alloy panel by using a second prediction model, sending the first process parameters to an autoclave, and controlling the autoclave to perform process operations with the first process parameters. The second prediction model is obtained by using a second training method on the initial network model; inputs of the second prediction model include process updating time, time, temperature, heating rate and pressure; outputs of the second prediction model include the predicted springback amount and yield strength of the aluminum alloy panel.

The method provided by this embodiment introduces collection devices such as a high-temperature strain gauge, a temperature sensor and a pressure sensor in a sealed vacuum bag to collect process data of the component in the autoclave. The process data can reflect real-time states of the component during the forming process in the autoclave, and is used to construct a prediction model with strain data, actual heating rate, mold-fitting time, pressure data, etc. as inputs, and the springback amount and mechanical properties of the component after forming as outputs. Since the prediction data in this embodiment is obtained based on the real-time states data of the component, prediction results are relatively accurate. And using the prediction data to adjust the process can ensure the component with precise forming and target performance.

Specifically, in an embodiment, the acquisition process of the first prediction model is as follows: conducting creep age forming tests on a specimen-level aluminum alloy and obtaining a sample data set; constructing a material constitutive equation using the sample data set; performing a finite element simulation on a creep age forming process of a component-level aluminum alloy panel, based on the material constitutive equation, and obtaining a corresponding relationship between strain amount and displacement of a feature point on the aluminum alloy panel at different times; determining, based on the corresponding relationship, initial process parameters of the aluminum alloy panel and the springback amount and yield strength at mold-fitting time during the finite element simulation process; taking the initial process parameters and the springback amount and yield strength at the mold-fitting time as first training samples and training the initial network model to obtain the first prediction model.

The sample data in this embodiment includes time, temperature, heating rate, stress size, creep amount, springback amount and yield strength obtained by conducting creep age forming tests on a standard creep sample made of aluminum alloy.

In this embodiment, creep age forming tests are conducted on a standard creep sample made of aluminum alloy, with the time, temperature, heating rate and stress size as inputs, and the creep amount as an output. After expanding the sample data through a machine learning method, the material constitutive equation is constructed. Based on the material constitutive equation, subsequent component-level finite element simulation is performed.

The material constitutive equation is:

$$ε1 = f ( σ , T , t , γ ) = f ( σ ) f ( T ) f ( γ ) f ( t ) , \qquad formula ( 1 ) ;$$

Wherein, ε1 is a creep strain; σ is an applied creep stress; T is a creep temperature; γ is a creep heating rate; t is a creep time, and f(σ), f(T), f(γ), f(t) are a creep stress function, a creep temperature function, a creep heating rate function and a creep time function, respectively.

The specifically machine learning method is a K-nearest neighbor algorithm. That is, the K-nearest neighbor algorithm is specifically used in this embodiment to expand the sample data. Using the K-nearest neighbor algorithm to expand the sample data, conducting creep age forming tests on a specimen-level aluminum alloy and obtaining an initial sample data set; determining an optimal setting range for a K-value in a K-nearest neighbor algorithm; setting the K-value in the K-nearest neighbor algorithm based on the optimal setting range, and expanding the initial sample data set based on the K-nearest neighbor algorithm with the K-value setting to generate a new sample data set.

It is found through comparison in this embodiment that when the K-value in the K-nearest neighbor algorithm is set within the range of 3, 4 and 5, a root mean square error (RMSE) of predicting different times, temperatures, heating rates and stress sizes of 2219 aluminum alloy is smaller. Therefore, the K-value range of 3, 4 and 5 can be selected in this embodiment. Expanding the sample data using this range can greatly reduce the creep sample test amount while forming a new sample data set with sufficient data amount.

During the finite element simulation process, a point on the aluminum alloy panel that is fitted to the mold under normal temperature loading is designated as a feature point. A mathematical model is established to map strain amount of the feature point to a forming state of the panel. An overall deformation state of the panel is obtained by analying the strain amount of the feature point under different conditions. That is, the corresponding relationship between the strain amount and displacement of the feature point on the aluminum alloy panel at different times is obtained.

Wherein, the corresponding relationship between strain amount and displacement of feature point on the aluminum alloy panel at different times includes:

$$ε2 = \frac{L - L 0}{L 0} , \qquad formula ( 2 )$$

Wherein, ε2 is the strain amount of the feature point on the aluminum alloy panel at different times, L0 represents a distance between an initial position of the feature point and the mold, and L denotes a distance between a position of the feature point on the aluminum alloy panel and the mold at different times.

After performing the finite element simulation process, a database can be established with inputs including time, temperature, heating rate, autoclave pressure, and strain amount of the feature point, and outputs including springback amount and yield strength of the aluminum alloy panel after creep forming is completed. Prediction models then be established through deep learning algorithms. The prediction models include the first prediction model and the second prediction model.

In an embodiment, training the initial network model and obtaining the first prediction model includes: selecting one of SGD, Adam, Adamax, or RMSprop as an algorithm optimizer for the LSTM algorithm model, and one of Sigmiod, Tanh, or ReLU as an activation function for the LSTM algorithm model; and training the initial network model with the selected algorithm optimizer and the selected activation function as model parameters to obtain the first prediction model.

A training process of the second prediction model includes: during the finite element simulation process, defining a time when room temperature loading is completed as a starting time, and a time when the aluminum alloy panel is completely fitted to the mold as an ending time; determining a plurality of process update times between the starting time and the ending time according to a preset process update frequency to obtain a process update time sequence; acquiring finite element simulation process data corresponding to each process update time in the process update time sequence; training the initial network model using the process update time sequence and the finite element simulation process data corresponding to each process update time in the process update time sequence as second training data, and obtaining the second prediction model.

Determining the plurality of process update times includes: defining a time when the room temperature loading is completed as a starting time T1, a time when the aluminum alloy panel is completely fitted the mold after the aluminum alloy panel is put into the autoclave for high-temperature loading as an ending time t1, a duration from T1 to t1 as T, and a process update frequency as f;

Then a process update time T2 is:

$$T 2 = T \times f + T 1 ;$$

A process update time T3 is:

$$T 3 = T \times f + T 2 ;$$

By analogy, a process update time Tn is:

$$Tn = T \times f + Tn - 1.$$

After the construction of the above prediction model is completed, the process parameters in the creep age forming process of the aluminum alloy panel can be adjusted according to the actual acquisition data of the aluminum alloy panel. That is, in this embodiment, the high-temperature strain gauge can be first attached to the position of the panel component that is not fitted with the mold, then loaded by compressing the vacuum bag, and the temperature sensor and the pressure sensor can be simultaneously fitted to the mold. Room temperature loading is first performed outside the autoclave, the previously determined initial process parameters are then input, and high temperature loading is performed by putting the panel component into the autoclave. The creep age forming test of the panel component is then started. Then, the autoclave, the mold, and the panel model are established through the digital twin software Unity3d on the computer side, and the strain gauge acquisition data, the temperature sensor data, and the pressure sensor data are connected to the computer side to construct the digital twin model of the creep age forming of the aluminum alloy panel. The rebound amount and the yield strength after the creep forming of the panel are then predicted through the data collected by the sensors in real time, and the process is adjusted in real time according to the target rebound amount and yield strength.

In the actual adjustment process, multiple adjustments can be made. That is, in an embodiment, after determining the first process parameter for updating the process of the aluminum alloy panel, sensor data of the aluminum alloy panel during the creep age forming process can be collected again after each preset time interval; the sensor data is input into the first prediction model to obtain the predicted springback amount and yield strength output by the first prediction model; the predicted springback amount and yield strength are compared with the target springback amount and yield strength to determine a first difference values between the predicted springback amount and yield strength and the target springback amount and yield strength; based on the first difference values, the second prediction model is used to determine the first process parameter for updating the process of the aluminum alloy panel, the first process parameter is sent to the autoclave, and the autoclave is controlled to perform a process operation with the first process parameter. The above operations are repeated until there is no difference between the predicted springback amount and yield strength and the target springback amount and yield strength.

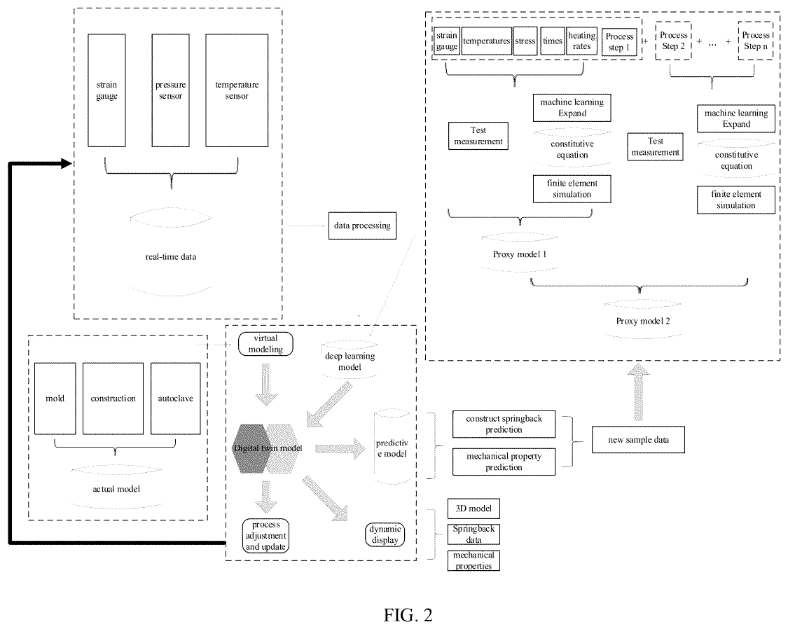

Specifically, referring to FIG. 2, a creep age forming process of a 2219 aluminum alloy panel will be described below.

Creep age forming tests are conducted on a specimen-level 2219 aluminum alloy. Different times, temperatures, heating rates, and strain gauge levels are used as input variables for the tests, and creep amounts are used as output variables for the tests. Creep age forming tests are conducted on the specimen-level 2219 aluminum alloy to obtain an initial specimen-level database (i.e., the initial sample data set). The data can be expanded by a machine learning method (e.g., a K-nearest neighbor algorithm). After comparison, it can be found that, when the K-value of the K-nearest neighbor algorithm is set within the range of 3, 4, or 5, the root mean square error (RMSE) of the predicted 2219 aluminum alloy at different times, temperatures, heating rates, and stress levels is smaller. By selecting the K-nearest neighbor algorithm with the optimal K-value range (i.e., K-value range of 3, 4, or 5) to expand the sample data volume, the amount of creep age forming tests can be significantly reduced, and a new sample data set can be formed with sufficient data volume.

Based on the sample data set, a material constitutive equation that relates the creep amount to the time, temperature, heating rate, and stress level is established as follows:

$$ε1 = f ( σ , T , t , γ ) = f ( σ ) f ( T ) f ( γ ) f ( t ) ;$$

Wherein, ε1 is a creep strain; σ is an applied creep stress; T is a creep temperature; γ is a creep heating rate; t is a creep time, and f(σ), f(T), f(γ), f(t) are a creep stress function, a creep temperature function, a creep heating rate function and a creep time function, respectively.

The finite element simulation of the creep age forming process of the component-level 2219 aluminum alloy panel is conducted by introducing the material constitutive equation, and the strain amount and displacement of the feature point at the same time are obtained. Through the finite element simulation, it can also be determined which feature points fail to fit to the mold when the room temperature loading is completed. Since the feature points that fail to fit to the mold can still displace, through finite element simulation results, the corresponding relationship between the strain amount ε2 and the real-time displacement L of these feature points can be established:

$$ε2 = \frac{L - L 0}{L 0} ;$$

Wherein, L0 is the distance between the initial position of the feature point and the mold, and L is the distance between the position of the feature point on the aluminum alloy panel and the mold at different times. Subsequently, by collecting the real-time strain amount through the strain gauge, real-time displacement of the feature point that fail to fit to the mold can be obtained. When the real-time displacement L is not changing, it is the fitting time.

In addition, the finite element simulation can be performed according to the target springback amount and yield strength of the component, and the initial process parameters can be determined. The initial process parameters are set as the initial process parameters of the creep age forming process of the autoclave.

The time, temperature, heating rate, and autoclave pressure during the above finite element simulation process (i.e., the initial process parameters) are used as the inputs of the initial network model (i.e., the LSTM algorithm model), and the yield strength and springback amount of the component after final forming (i.e., the springback amount and yield strength at the fitting time) are used as the outputs of the initial network model. Before learning and training, the data in the new sample data set can be processed by regular standardization.

The algorithm optimizer for the initial network model can be selected as any one of SGD, Adam, Adamax and RMSprop, and the activation function can be selected as any one of Sigmiod, Tanh and ReLU. Selecting the optimal algorithm optimizer and activation function therefrom can obtain the first prediction model with a highest accuracy.

Then, the time when the room temperature loading during the finite element simulation process is completed is defined as the starting time T1, and the time when the panel is completely fitted to the mold is defined as the ending time t1. Starting from T1 and ending at t1, the duration from T1 to t1 is defined as T. The process update frequency is defined as f. According to the process update frequency, the duration T can be divided into a plurality of process update times T1, T2, T3, . . . , Tn (i.e., a process update time sequence is obtained).

The process update time T2 is:

$$T 2 = T \times f + T 1 ;$$

The process update time T3 is:

$$T 3 = T \times f + T 2 ;$$

By analogy, the process update time Tn is:

$$Tn = T \times f + Tn - 1.$$

The finite element simulation process data at the different process update times T1, T2, T3, . . . , Tn are obtained as the second training samples, and after training the initial network model, the second prediction model is obtained that can quickly predict the outputs (i.e., the springback amount and yield strength of the aluminum alloy panel) by inputting the process parameters (i.e., the process update time, time, temperature, heating rate and pressure).

The above is the training process of the first prediction model and the second prediction model. Based on the established first prediction model and the second prediction model, the creep age forming process of the aluminum alloy panel can be controlled.

That is, high-temperature strain gauges are first attached to a position where the panel component is not fitted with the mold to monitor the molding condition. Loading is then performed by compressing the vacuum bag, while the temperature sensor and the pressure sensor are simultaneously attached to the mold. A room temperature loading is first performed outside the autoclave, followed by inputting the initial process parameters, and creep age forming test of the panel component is started.

The three-dimensional CAD models of the autoclave, the mold, and the panel model are imported into a Unity3d software. The data collected by the strain gauge, the temperature sensor, and the pressure sensor are integrated into the Unity3d software through serial communication or intranet TCP communication. In the Unity3d software, the actual pressure changes, time changes, and heating rates in the autoclave can be observed in real time. At the same time, the real-time three-dimensional states and stress distribution of the entire panel component are dynamically displayed. The pseudo code is as follows:

$$float pressure = float \cdot Parse ( values [ 0 ] ) ;$$

$$float temperature = float \cdot Parse ( values [ 1 ] ) ;$$

$$float strain = float \cdot Parse ( values [ 2 ] ) ;$$

$$float currentTime = Time \cdot time - startTime ;$$

$$float heatingRate = ( temperature - lastTemperature ) / ( currentTime - lastTime ) ;$$

$$lastTemperature = temperature ;$$

$$lastTime = currenTime ;$$

UpdateDisplay (pressure, temperature, strain, currentTime, heatingRate).

The actual data collected by the current sensor, i.e., the molding situations, pressure changes inside the autoclave, time changes, and heating rates during the actual process, are displayed in a form of table. Meanwhile, the first prediction model is called, and the molding situations, pressure changes in the autoclave, time changes, and heating rates during the actual process are input into the first prediction model. The springback amount and yield strength of the formed component are predicted, and are displayed in a form of a cloud map in Unity3d.

The predicted springback amount and yield strength are compared with the target springback amount and yield strength, and the process parameters at different process update times T1, T2, T3, . . . , Tn are updated using the comparison results. The process parameters at different process update times T1, T2, T3, . . . , Tn are repeatedly updated and iterated until the springback amount and yield strength of the formed component predicted by the second prediction model meet the target springback amount and yield strength, after the updated process parameters at different process update times T1, T2, T3, . . . , Tn are input into the second prediction model. The autoclave is controlled to perform process operations according to the updated process parameters at different process update times. The predicted dynamic final target springback amount and yield strength are displayed in the form of the cloud map. The pseudo code is as follows:
SelectNewProcess (actualSpringback, actual YieldStrength);
SendProcessUpdateToAutoclave(currentProcess);
Float [,] predictionData=GetPredictionData( );
cloudMap.UpdateCloudMap(predictionData);
string finalProcessName=“Process”+(iterationCount+1);
finalProcessText.text=“finalActualProcess”+finalProcessName.

The digital-twin-based forming monitoring of the creep age forming of component-level 2219 aluminum alloy panel can be completed.

The creep age forming method based on digital twin technology provided by the embodiments of the present disclosure acquires sensor data of the aluminum alloy panel during the creep age forming process; inputs the sensor data into the first prediction model and obtains the predicted springback amount and yield strength output by the first prediction model; compares the predicted springback amount and yield strength with the target springback amount and yield strength; determines the first difference values between the predicted springback amount and yield strength and the target springback amount and yield strength; based on the first difference values, determines first process parameters for updating the process of the aluminum alloy panel by using the second prediction model; sends the first process parameters to the autoclave, and controls the autoclave to perform a process operation with the first process parameters. The solution provided by the present disclosure can adjust the process based on real-time sensor data to obtain components with precise forming and target performance.

An embodiment of the present disclosure provides a creep age forming device based on digital twin technology. The creep age forming device based on digital twin technology includes:
a sealed vacuum bag, an autoclave, a high-temperature strain gauge, a temperature sensor, a pressure sensor and a processor;
the sealed vacuum bag is connected to the high-temperature strain gauge, the temperature sensor and the pressure sensor, and is used for shrinking during a vacuum pumping process to make the component fit the mold; the autoclave is connected to the high-temperature strain gauge, the temperature sensor and the pressure sensor, and is used for making the component fit the mold; the autoclave is connected with the high-temperature strain gauge, the temperature sensor and the pressure sensor, and is used for entering a creep age forming stage after the component is fitted to the mold under heating and pressure conditions; the high-temperature strain gauge is used for collecting state data of the component; the temperature sensor is configured to collect temperature data, and the pressure sensor is configured to collect pressure data; and the processor is used for executing the steps of the method described above.

From the above embodiments, it can be seen that the embodiments have the following advantages:
1. Traditionally, creep age forming becomes a “black box problem” after the mold and the panel are placed in the autoclave, and a final state of the panel can only be known after the process (often lasting more than 10 hours) is completed. The present disclosure can monitor the state of the panel in real time and predict the final state of the panel, thereby improving the forming efficiency.
2. Compared to the traditional creep age forming that the process can only be formulated in advance by using offline finite element simulation technology, and the influence of errors in the actual molding time and state, temperature, heating rate, pressure of the equipment cannot be considered. The present disclosure can adjust the process in real-time real by collecting real-time real data through sensors to achieve precise forming.
3. The digital twin system is trained on big data, and expands the database through real test data, resulting in higher prediction accuracy of the prediction model. The present disclosure can learn from completed tests organically. Unlike the traditional completed tests, there is often no connection established between completed tests to provide guidance for subsequent tests.
4. Since the autoclave is a special high-temperature and high-pressure equipment, an operating platform of the traditional test is beside the autoclave, which posed a certain degree of danger to the operators. The digital twin system can remotely operate the autoclave in the cloud, thereby reducing the danger of the operators.

The solution provided by the present disclosure can adjust the process based on real-time sensor data to obtain components with precise forming and target performance.

In order to implement the method of the embodiments of the present disclosure, the embodiments of the present disclosure further provide a computer program product, and the computer program product includes computer instructions stored in a computer-readable storage medium. A processor of a computer device reads the computer instructions from the computer-readable storage medium, and the processor executes the computer instructions to cause the computer device to perform the steps of the aforementioned method.

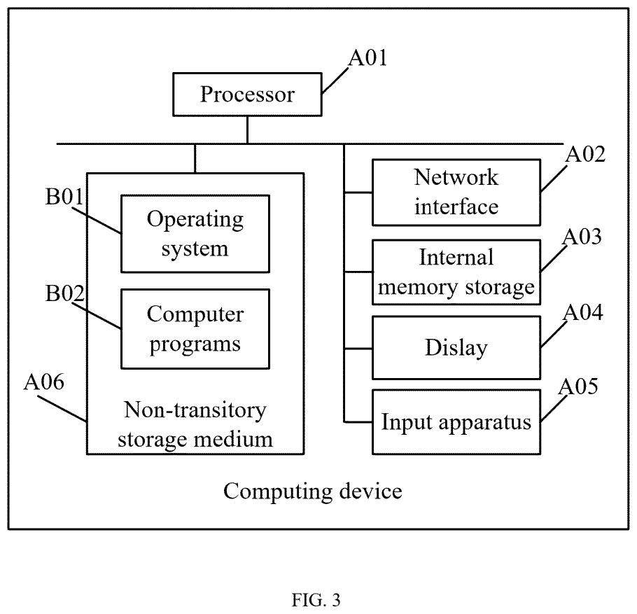

Based on the hardware implementation of the above program modules, and to implement the method of the embodiments of the present disclosure, the embodiments of the present disclosure also provide an electronic device (computer device). Specifically, in one embodiment, the computer device can be a terminal, and its internal structure diagram is illustrated in FIG. 3. The computer device includes a processor A01, a network interface A02, a display screen A04, an input device A05 and a memory (not shown in the figure), all connected through a system bus. Wherein, the processor A01 of the computer device is configured to provide calculation and control capabilities. The memory of the computer device includes an internal memory A03 and a non-volatile storage medium A06. The non-volatile storage medium A06 stores an operating system B01 and a computer program B02. The internal memory A03 provides an environment for the running of the operating system B01 and the computer program B02 stored in the non-volatile storage medium A06. The network interface A02 of the computer device is used to communicate with external terminals through network connection. The computer program is executed by the processor A01 to implement the method of any one of the above embodiments. The display screen A04 of the computer device can be a liquid crystal display screen or an electronic ink display screen, and the input device A05 of the computer device can be a touch layer overlaid on the display screen, or can be a key, a trackball or a touchpad provided on the shell of the computer device, or can be an external keyboard, a touchpad or a mouse, etc.

Those skilled in the art can understand that the structure shown in FIG. 3 is merely a block diagram of parts of the structure related to the solution of the present disclosure, and does not constitute a limitation on the computer device to which the solution of the present disclosure is applied. A specific computer device can include more or fewer components than those shown in the figure, or combine certain components, or have a different component arrangement.

The device provided by the embodiments of the present disclosure includes a processor, a memory and a program stored in the memory and executable on the processor. When the processor executes the program, the method of any one of the above embodiments is implemented.

Those skilled in the art should understand that the embodiments of the present disclosure can be provided as a method, a system, or a computer program product. Therefore, the present disclosure can take a form of a purely hardware embodiment, a purely software embodiment, or an embodiment combining aspects of both software and hardware. Furthermore, the present disclosure can take a form of a computer program product implemented on one or more computer-usable storage media (including but not limited to disk storage, CD-ROM, optical storage, etc.) containing computer-usable program code.

The present disclosure is described with reference to flowcharts and/or block diagrams of methods, devices (systems), and computer program products according to embodiments of the present disclosure. It should be understood that, each process and/or block in the flowcharts and/or block diagrams, as well as combinations of processes and/or blocks in the flowcharts and/or block diagrams, can be implemented by computer program instructions. These computer program instructions can be provided to a processor of a general-purpose computer, a special-purpose computer, an embedded processor, or other programmable data processing device, to generate a machine that, when the instructions are executed by the processor of the computer or other programmable data processing device, produces a means for implementing the functions specified in one or more processes of the flowchart and/or one or more blocks of the block diagram.

These computer program instructions can also be stored in a computer-readable memory that can direct a computer or other programmable data processing devices to operate in a particular manner, such that the instructions stored in the computer-readable memory produce an article of manufacture including instruction means which implement the functions specified in one or more processes of the flowchart and/or one or more blocks of the block diagram.

These computer program instructions can also be loaded onto a computer or other programmable data processing devices, causing the computer or other programmable device to execute a series of operational steps to produce a computer-implemented process, whereby the instructions executed on the computer or other programmable devices provide steps for implementing the functions specified in one or more processes of the flowchart and/or one or more blocks of the block diagram.

In a typical configuration, the computing device includes one or more processors (CPUs), an input/output interface, a network interface, and a memory.

The memory may include a non-permanent memory in computer-readable media, a Random Access Memory (RAM), and/or non-volatile memory, such as Read-Only Memory (ROM) or flash memory (flash RAM). Memory is an example of a computer-readable medium.

Computer-readable media, includes both permanent and non-permanent, removable and non-removable media, and can achieve information storage through any method or technology. The information can be computer-readable instructions, data structures, program modules, or other data. Examples of computer storage media include, but are not limited to, phase change memory (PRAM), static random access memory (SRAM), dynamic random access memory (DRAM), other types of random access memory (RAM), read-only memory (ROM), electrically erasable programmable read-only memory (EEPROM), flash memory, or other memory technologies, compact disc read-only memory (CD-ROM), digital versatile disc (DVD), or other optical storage, magnetic cassettes, magnetic tape, magnetic disk storage, or other magnetic storage devices, or any other non-transitory media that can be used to store information accessible by a computing device. In accordance with the definition provided in the present disclosure, computer-readable media does not include transitory computer-readable media, such as modulated data signals and carrier waves.

It is understood that the memory in the embodiments of the present disclosure can be volatile memory or non-volatile memory, or can include both volatile and non-volatile memory. Among them, non-volatile memory can be Read-Only Memory (ROM), Programmable Read-Only Memory (PROM), Erasable Programmable Read-Only Memory (EPROM), Electrically Erasable Programmable Read-Only Memory (EEPROM), ferromagnetic random-access memory (FRAM), Flash Memory, magnetic surface storage, optical discs, or Compact Disc Read-Only Memory (CD-ROM); magnetic surface storage can be disk storage or tape storage. Volatile memory can be Random Access Memory (RAM), which is used as external cache. By way of example and not limitation, many forms of RAM are available, such as Static Random Access Memory (SRAM), Synchronous Static Random Access Memory (SSRAM), Dynamic Random Access Memory (DRAM), Synchronous Dynamic Random Access Memory (SDRAM), Double Data Rate Synchronous Dynamic Random Access Memory (DDR SDRAM), Enhanced Synchronous Dynamic Random Access Memory (ESDRAM), SyncLink Dynamic Random Access Memory (SLDRAM), and Direct Rambus Random Access Memory (DRRAM). The memory described in the embodiments of the present disclosure is intended to include, but is not limited to, these and any other suitable types of memory.

It should also be noted that the terms “comprise” or “include” or any other variations thereof, are intended to cover a non-exclusive inclusion, such that processes, methods, articles, or apparatuses that include a list of elements do not include only those elements, but can include other elements not expressly listed or inherent to such processes, methods, articles, or apparatuses. An element proceeded by “include one” does not, without more constraints, preclude the existence of additional identical elements in the process, method, article, or apparatus that comprises the element.

The above embodiments are only used to illustrate the technical solutions of the present disclosure, and are not limited to the present disclosure. For those skilled in the art, the present disclosure can have various modifications and variations. Any modification, equivalent replacement, improvement, etc. made within the spirit and principle of the present disclosure should be fall within the protection scope of the claims of the present disclosure.

What is claimed is:

1. A creep age forming method based on digital twin technology, comprising:
acquiring sensor data of an aluminum alloy panel during a creep age forming process;
inputting the sensor data into a first prediction model and obtaining a predicted springback amount and yield strength output by the first prediction model, wherein, the first prediction model is obtained by using a first training method on an initial network model, and the initial network model is an LSTM algorithm model; inputs of the first prediction model comprise time, temperature, heating rate, and pressure; outputs of the first prediction model comprise the predicted springback amount and yield strength of the aluminum alloy panel;
comparing the predicted springback amount and yield strength with a target springback amount and yield strength, and determining first difference values between the predicted springback amount and yield strength and the target springback amount and yield strength;
determining, based on the first difference values, first process parameters for updating a process of the aluminum alloy panel by using a second prediction model;
sending the first process parameters to an autoclave, and controlling the autoclave to perform process operations with the first process parameters; wherein, the second prediction model is obtained by using a second training method on the initial network model; inputs of the second prediction model comprise process updating time, time, temperature, heating rate, and pressure; outputs of the second prediction model comprise the predicted springback amount and yield strength of the aluminum alloy panel;
wherein, the step of obtaining the first prediction model comprises:
conducting creep age forming tests on a specimen-level aluminum alloy and obtaining a sample data set;
constructing a material constitutive equation using the sample data set;
performing a finite element simulation on a creep age forming process of a component-level aluminum alloy panel, based on the material constitutive equation, and obtaining a corresponding relationship between strain amount and displacement of a feature point on the aluminum alloy panel at different times;
determining, based on the corresponding relationship, initial process parameters of the aluminum alloy panel and the springback amount and yield strength at mold-fitting time during the finite element simulation process;
taking the initial process parameters and the springback amount and yield strength at the mold-fitting time as first training samples and training the initial network model to obtain the first prediction model;
wherein, the step of obtaining the second prediction model comprises:
during the finite element simulation process, defining a time when room temperature loading is completed as a starting time, and a time when the aluminum alloy panel is completely fitted to the mold as an ending time; determining a plurality of process update times between the starting time and the ending time according to a preset process update frequency to obtain a process update time sequence;
acquiring finite element simulation process data corresponding to each process update time in the process update time sequence;
training the initial network model using the process update time sequence and the finite element simulation process data corresponding to each process update time in the process update time sequence as second training data, and obtaining the second prediction model.

2. The method according to claim 1, wherein the material constitutive equation comprises:
$$ε1 = f ( σ , T , t , γ ) = f ( σ ) f ( T ) f ( γ ) f ( t ) ; \qquad Formula ( 1 )$$
wherein, ε1 is a creep strain; σ is an applied creep stress; T is a creep temperature; γ is a creep heating rate; t is a creep time, and f(σ), f(T), f(γ), f(t) are a creep stress function, a creep temperature function, a creep heating rate function and a creep time function, respectively.

3. The method according to claim 1, wherein the step of obtaining the sample data set comprises:
conducting creep age forming tests on a specimen-level aluminum alloy and obtaining an initial sample data set;
determining an optimal setting range for a K-value in a K-nearest neighbor algorithm;
setting the K-value in the K-nearest neighbor algorithm based on the optimal setting range, and expanding the initial sample data set based on the K-nearest neighbor algorithm with the K-value setting to generate a new sample data set.

4. The method according to claim 1, wherein the corresponding relationship between strain amount and displacement of feature point on the aluminum alloy panel at different times comprises:
$$ε2 = \frac{L - L 0}{L 0} , \qquad formula ( 2 )$$
wherein, ε2 is the strain amount of the feature point on the aluminum alloy panel at different times, L0 represents a distance between an initial position of the feature point and the mold, and L denotes a distance between a position of the feature point on the aluminum alloy panel and the mold at different times.

5. The method according to claim 4, wherein the step of training the initial network model to obtain the first prediction model comprises:
selecting one of SGD, Adam, Adamax, or RMSprop as an algorithm optimizer for the LSTM algorithm model, and one of Sigmiod, Tanh, or ReLU as an activation function for the LSTM algorithm model;
training the initial network model with the selected algorithm optimizer and the selected activation function as model parameters to obtain the first prediction model.

6. The method according to claim 5, wherein the step of determining the plurality of process update times comprises:
defining a time when the room temperature loading is completed as a starting time T1, a time when the aluminum alloy panel is completely fitted to the mold after the aluminum alloy panel is put into the autoclave for high-temperature loading as an ending time t1, a duration from T1 to t1 as T, and a process update frequency as f;
then a process update time T2 is:
$$T 2 = T \times f + T 1 ;$$
a process update time T3 is:
$$T 3 = T \times f + T 2 ;$$
by analogy, a process update time Tn is:
$$Tn = T \times f + Tn - 1.$$

7. The method according to claim 1, after determining the first process parameters for updating the process of the aluminum alloy panel, the method further comprising:
after a preset time interval, acquiring sensor data of the aluminum alloy panel during the creep age forming process again; inputting the sensor data into the first prediction model and obtaining the predicted springback amount and yield strength output by the first prediction model; comparing the predicted springback amount and yield strength with the target springback amount and yield strength, and determining the first difference values between the predicted springback amount and yield strength and the target springback amount and yield strength; based on the first difference values, determining the first process parameters for updating the process of the aluminum alloy panel by using the second prediction model, sending the first process parameters to the autoclave, and controlling the autoclave to perform a process operation according to the first process parameters, and repeating the above operations until the predicted springback amount and yield strength are no difference from the target springback amount and yield strength.

8. A creep age forming device based on digital twin technology, comprising:
a sealed vacuum bag, an autoclave, a high-temperature strain gauge, a temperature sensor, a pressure sensor and a processor; the sealed vacuum bag is connected to the high-temperature strain gauge, the temperature sensor and the pressure sensor, and is used for shrinking during a vacuum pumping process to make the component fit the mold; the autoclave is connected to the high-temperature strain gauge, the temperature sensor and the pressure sensor, and is used for making the component fit the mold; the autoclave is connected with the high-temperature strain gauge, the temperature sensor and the pressure sensor, and is used for entering a creep age forming stage after the component is fitted to the mold under heating and pressure conditions; the high-temperature strain gauge is used for collecting state data of the component; the temperature sensor is configured to collect temperature data, and the pressure sensor is configured to collect pressure data; and the processor is configured to execute the steps of the method according to claim 1.
